(19) United States
(12) Patent Application Publication
(10) Pub. No.: US 2023/0246417 A1
(43) Pub. Date: Aug. 3, 2023

(54) TUNABLE LASER HAVING RING RESONATORS WITH LOW Q

(71) Applicant: Marvell Asia Pte Ltd, Singapore (SG)

(72) Inventors: Xiaoguang HE, Diamond Bar, CA (US); Radhakrishnan Nagarajan, Santa Clara, CA (US)

(21) Appl. No.: 18/097,423

(22) Filed: Jan. 16, 2023

Related U.S. Application Data
(60) Provisional application No. 63/304,945, filed on Jan. 31, 2022.

(51) Int. Cl. H01S 5/14; H01S 5/10; H01S 5/02325; H01S 5/026

(52) U.S. Cl. CPC H01S 5/142; H01S 5/1032; H01S 5/02325; H01S 5/0265

(57) ABSTRACT

A tunable laser for generating and outputting wavelength-tuned light using only a single gain chip includes a reflective semiconductor optical amplifier (RSOA) having a front-end configured as an output port for outputting the wavelength-tuned light with an amplified light intensity relative to light received at a back-end of the RSOA. A wavelength tuner is optically coupled to the back-end of the RSOA and includes a plurality of ring resonators having respective Q-factors above 2000 and below 4000.

### CROSS REFERENCES TO RELATED APPLICATIONS

This application claims the benefit of U.S. Provisional Patent Application No. 63/304,945, entitled “Tunable Laser with Low Q Ring Resonators,” filed on Jan. 31, 2022, the disclosure of which is hereby expressly incorporated herein by reference in its entirety.

### FIELD OF TECHNOLOGY

The present disclosure relates generally to optical communications, and more particularly to tunable lasers for use in optical communication devices.

### BACKGROUND

During this time of growth of Internet technologies and usage, demand for high speed data transmission has increased rapidly. As an example, average internet traffic in 2021 was estimated to exceed 700 terabytes per second. Technologies to support such sustained usage levels will continue to proliferate. Optical transmission of data can support vast amounts of data per channel—often limited more by the rate at which electronics can encode a signal onto the optical channel rather than the bandwidth of the channel itself Improvements to optical modulation performance will continue to drive adoption of such technologies.

### SUMMARY

In an embodiment, a tunable laser for generating and outputting wavelength-tuned light using only a single gain chip comprises: a reflective semiconductor optical amplifier (RSOA) having a front-end configured as an output port for outputting the wavelength-tuned light with an amplified light intensity relative to light received at a back-end of the RSOA; and a wavelength tuner optically coupled to the back-end of the RSOA, the wavelength tuner comprising a plurality of ring resonators having respective Q-factors above 2000 and below 4000.

In another embodiment, a method for operating a single gain chip tunable laser includes: generating, by an RSOA, light; passing the light generated by the RSOA to a wavelength tuner via a back-end of the RSOA; and inducing respective frequency shifts in the light by a plurality of ring resonators of the wavelength tuner, each ring resonator having a respective quality factor (Q-factor) between 2000 and 4000; generating, with the wavelength tuner, wavelength-tuned light having a peak at a particular frequency corresponding to a difference between resonant frequency shifts caused by the plurality of ring resonators; passing the wavelength-tuned light back to the RSOA via the back-end of the RSOA; and outputting the wavelength-tuned light from the RSOA via a front-end of the RSOA.

In yet another embodiment, a method of manufacturing a tunable laser that is configured to generate and output wavelength-tuned light using only a single gain chip includes: fabricating a wavelength tuner on a semiconductor substrate, including fabricating on the semiconductor substrate a plurality of ring resonators having respective Q-factors above 2000 and below 4000; and mounting the single gain chip on the semiconductor substrate, the single gain chip comprising an RSOA with a front-end configured to output wavelength-tuned light, wherein the single gain chip is mounted so that a back-end of the RSOA is optically coupled to the wavelength tuner.

### BRIEF DESCRIPTION OF THE DRAWINGS

FIG. 1 is a simplified diagram of an example tunable laser device having only a single gain chip, according to an embodiment.

FIG. 2 is a plot of maximum output of the tunable laser device of FIG. 1 versus a quality factor (Q-factor) of ring resonators of the tunable laser device of FIG. 1, according to an embodiment.

FIG. 3 is a plot of side mode suppression ratio (SMSR) of the tunable laser device of FIG. 1 versus a coupling coefficient, and a plot of the Q-factor of the ring resonators of the tunable laser device of FIG. 1 versus the coupling coefficient, according to an embodiment.

FIG. 4 is a plot of loss in a wavelength tuner of the tunable laser device of FIG. 1 versus a coupling coefficient, and a plot of the Q-factor of the ring resonators of the tunable laser device of FIG. 1 versus the coupling coefficient, according to an embodiment.

FIG. 5 is a diagram of a section of a ring resonator and a section of a waveguide of the tunable laser device of FIG. 1, magnified to illustrate an optical coupling of the ring resonator and the waveguide, according to an embodiment.

FIG. 6 is a plot of optical output power of the tunable laser of FIG. 1 versus wavelength, according to an embodiment.

FIG. 7 is a plot of optical output power and SMSR of the tunable laser of FIG. 1 versus wavelength, according to an embodiment.

FIG. 8 is a flow diagram of an example method of operation of a tunable laser implemented using only a single gain chip, according to an embodiment.

FIG. 9 a flow diagram of an example method of manufacturing a tunable laser having only a single gain chip, according to an embodiment.

### DETAILED DESCRIPTION

Tunable lasers are a key component in many optical communication modules. A challenge for tunable laser design is to achieve a high power optical output (such as greater than 18 decibel-milliwatts (dBm) while keeping power consumption relatively low (such as less than 2.2 Watts).

Some emerging tunable laser devices achieve high optical output power with two gain chips in a chip package, e.g., a reflective semiconductor optical amplifier (RSOA) chip and a semiconductor optical amplifier (SOA) chip, along with a tuner. In some designs, the tuner is placed at an output side of the RSOA, resulting in a large optical penalty that increases power consumption in order to achieve a desired output power. In other designs, the tuner is placed at a side of the RSOA opposite the output and the SOA is optically coupled to the RSOA chip. However, optical components required for coupling the RSOA with the SOA introduce loss, which requires increased power consumption to achieve a desired output power.

The present application describes embodiments of tunable laser devices that utilize a single gain chip to achieve a desired optical output power. Because only a single gain chip is utilized, the power consumption of the tunable laser device is kept relatively low, at least in some embodiments. For example, a tunable laser device with a single gain chip provides greater than 18 dBm optical output power while keeping power consumption below 2.2 Watts, at least in some embodiments.

In some embodiments, the single gain chip of the tunable laser device comprises a reflective semiconductor optical amplifier (RSOA). A wavelength tuner is optically coupled to a back-end of the RSOA, and the wavelength tuner comprises a plurality of ring resonators having respective Q-factors that are above 2000 and below 4000, according to some embodiments. The use of ring resonators with Q-factors that are above 2000 and below 4000, results in a single gain chip tunable laser with a relatively high optical output power (e.g., 18 dBm) and a relatively low power consumption (e.g., below 2.2 Watts), according to some embodiments.

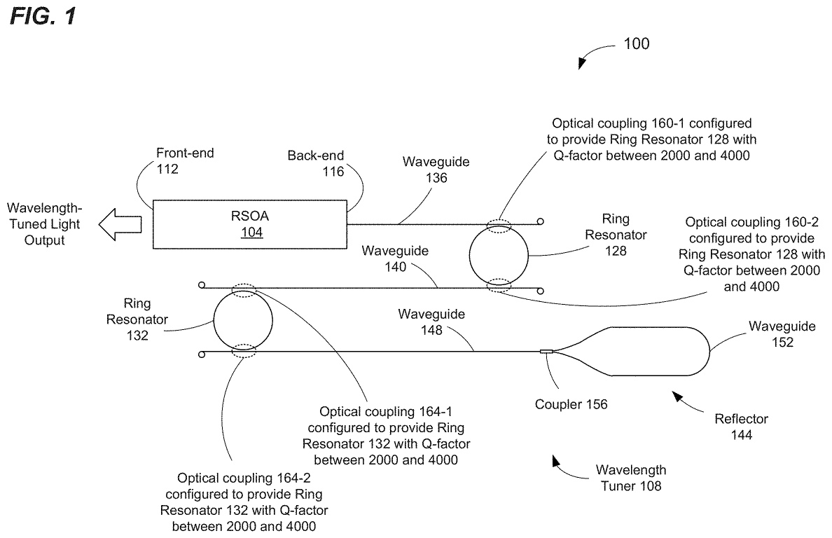

FIG. 1 is a simplified diagram of an example tunable laser device 100, according to an embodiment. The tunable laser device 100 comprises an RSOA 104 coupled to a wavelength tuner 108. The RSOA 104 comprises a front-end 112 and a back-end 116. The front-end 112 is configured as a laser output port that outputs wavelength-tuned light. The back-end 116 is configured to allow light to pass between the RSOA 104 and the wavelength tuner 108.

In some embodiments, the RSOA 104 comprises a diode-based optical amplifier having a gain medium cavity with a length L_{G} between the front-end 112 and the back-end 116. Generally, as the length L_{G} increases the light power gain produced by the RSOA 104 increases, and thus the length L_{G} is selected so that the tunable laser 100 has a desired output power. In some embodiments, the RSOA 104 is configured to have a length L_{G} of approximately 1.5 mm (i.e., 1.5 mm±0.075 mm) In some embodiments, the RSOA 104 is configured to have a length L_{G} of approximately 1.75 mm (i.e., 1.75 mm±0.0875 mm) In some embodiments, the RSOA 104 is configured to have a length L_{G} of approximately 2 mm (i.e., 2 mm±0.1 mm) In some embodiments, the RSOA 104 is configured to have a length L_{G} of at least 1.5 mm. In some embodiments, the RSOA 104 is configured to have a length L_{G} of at least 1.425 mm and at most 2.5 mm. In some embodiments, the RSOA 104 is configured to have a length L_{G} of between 1.4 and 2.1 mm. In other embodiments, the RSOA 104 is configured to have another suitable length L_{G}.

The RSOA 104 is implemented as a single gain chip mounted on a silicon photonics platform, which comprises a silicon semiconductor substrate, according to some embodiments. The single gain chip is flip-mounted to the silicon photonics platform, in an embodiment.

In some embodiments, the front-end 112 comprises a low-reflectivity facet configured to have a reflectivity within a range of 1% to 8%. In some embodiments, the reflectivity of the facet of the front-end is within a range of 2% to 7%. In some embodiments, the reflectivity of the facet of the front-end is set to approximately 5% (i.e., 5%±0.25%). In some embodiments, the reflectivity of the facet of the front-end is within a range of 1% to 20%. In other embodiments, the reflectivity of the facet of the front-end has another suitable value.

The back-end 116 comprises a facet coated by an anti-reflective coating configured to make the facet substantially transparent for light emitted in the gain medium of the RSOA 104 to pass to the wavelength tuner 108 and for light from the wavelength tuner 108 to pass back to the gain medium of the RSOA 104, according to an embodiment.

The wavelength tuner 108 comprises a plurality of ring resonators, including a ring resonator 128 and a ring resonator 132. In some embodiments, the ring resonators 128, 132 comprise generally circular-shaped waveguides. In some embodiments, the generally circular-shaped waveguides are formed in a silicon photonics platform. For example, the ring resonators 128, 132 comprise silicon or silicon nitride wire waveguides formed in a silicon substrate, in some embodiments.

The wavelength tuner 108 also comprises a plurality of waveguides, including a waveguide 136 and a waveguide 140, that optically coupled the ring resonators 128, 132 to the RSOA 104. For example, the waveguide 136 optically couples the RSOA 104 and the ring resonator 128, and the waveguide 140 optically couples the ring resonator 128 and the ring resonator 132.

The wavelength tuner 108 further comprises a reflector 144 optically coupled to the plurality of ring resonators. For example, the reflector 144 is optically coupled to the ring resonator 132 via a waveguide 148. In some embodiments, the reflector 144 comprises a loop reflector having a waveguide 152 arranged in a loop and coupled to an optical coupler 156. In some embodiments, the waveguide 152 and the optical coupler 156 are formed in a silicon photonics platform. For example, the reflector 144 comprises a silicon or silicon nitride wire waveguide formed in a silicon substrate, in some embodiments. The reflector 144 omits an external splitting branch and is configured to cause light substantially (e.g., greater than 90%) to be returned back to the waveguide 148, according to an embodiment. Generally, the reflector 144 is designed to have a suitable reflectivity near 100% to allow light to substantially reflect towards the RSOA 104.

Although the reflector 144 is illustrated in FIG. 1 as a loop reflector, in other embodiments the reflector 144 comprises another suitable optical reflector.

In some embodiments, the waveguides 136, 140, 148, are formed in a silicon photonics platform. For example, the waveguides 136, 140, 148 comprise silicon or silicon nitride wire waveguides formed in a silicon substrate, in some embodiments.

In operation, the RSOA 104 generates light which exits the RSOA 104 via the back-end 116. The waveguide 136 receives light from the backend 116 of the RSOA 104 and guides the light to the ring resonator 128, which induces a first resonant frequency shift to the light. Additionally, the waveguide 140 guides light from the ring resonator 128 to the ring resonator 132, which induces a second resonant frequency shift to the light. The ring resonator 128 and the ring resonator 132 have different diameters for generating different phase shifts for light traveling through the ring resonator 128 and traveling through the ring resonator 132. In an embodiment, the ring resonator 128 has a diameter of approximately 24 micrometers (μm) (i.e., 24 μm±0.24 μm) and the ring resonator 132 has a larger diameter of at about 25 μm (i.e., 25 μm±0.25 μm). In other embodiments, the ring resonator 128 and the ring resonator 132 have other suitable diameters.

Additionally, light is guided by the waveguide 148 to the reflector 144. Light returned back to the waveguide 148 by the reflector 144 generates a light interference spectrum with a sharp peak at a specific wavelength with all side modes being substantially suppressed or filtered, where the specific wavelength corresponds to a desired frequency output of the tunable laser device 100. The specific wavelength is determined based on a difference between a first resonant frequency shift caused by the ring resonator 128 and a second resonant frequency shift caused by the ring resonator 132, where the difference between the first resonant frequency shift and the second resonant frequency shift is dependent upon a difference in respective diameters of the ring resonator 128 and the ring resonator 132, as well as any phase change around the ring resonator 128 and the ring resonator 132. The phase change can be caused externally, for example, by adding a respective heater on top of each of the ring resonator 128 and the ring resonator 132 to change respective temperatures of the ring resonator 128 and the ring resonator 132. Thus, the specific peak wavelength in the light interference spectrum can be tuned within a certain tunable range. Optionally, the tunable range of the wavelength tuner 108 includes the entire C-band or the entire O-band, depending on application. Eventually, the light with a specifically tuned wavelength is returned to the RSOA 104. The intensity of the wavelength-tuned light is amplified by the RSOA 104, and the wavelength-tuned light is output via the front-end 112.

The ring resonator 128 and the ring resonator 132 each have a respective quality factor (Q-factor). The Q-factor of a resonator is a measure of a strength of a damping of oscillations caused by the ring resonator. In a first definition, the Q-factor is defined as 27π times a ratio of stored energy to energy dissipated per oscillation cycle. In a second definition, the Q-factor is defined as:

Q=v₀/δv Equ. 1

where v₀ is the resonance frequency of the ring resonator, and δv is a full width at half-maximum (FWHM) bandwidth of the resonance. The first definition and the second definition are generally equivalent in the limit of weakly damped oscillations, i.e., for high Q-factor values.

Generally, a side mode suppression ratio (SMSR) of a tunable laser decreases as the Q-factor of resonators of the tunable laser decreases. This suggests that excessive reduction in resonator Q-factor values results in unsuitable tunable lasers with unacceptably low SMSRs. Nevertheless, the inventors have found that the use of resonators with lower Q-factor values decreases optical loss in the wavelength tuner 108 while still providing acceptable SMSR. Thus, the inventors have found that, contrary to the general suggestion that use of resonators with low Q-factor values results in unacceptable SMSR values, the use of resonators with low Q-factor values, such as below 4000, provides a tunable laser with high output power, low power consumption, and acceptable SMSR.

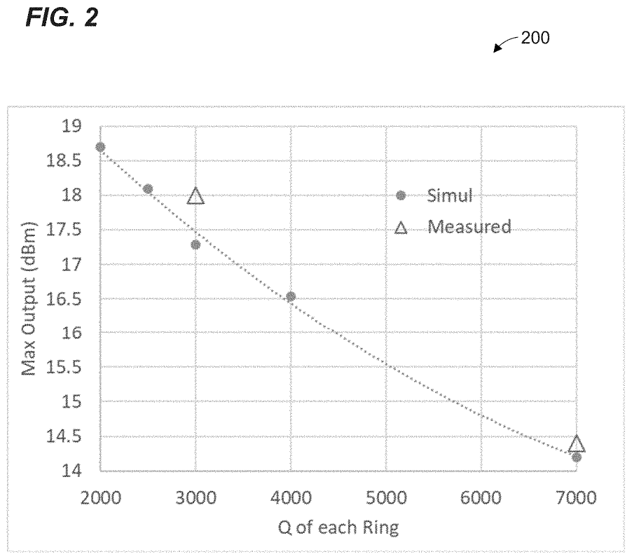

FIG. 2 is a plot 200 of maximum output of the tunable laser device 100 versus the Q-factor of the ring resonators 128, 132, according to an embodiment. As can be seen in FIG. 2, the maximum output of the tunable laser device 100 increases as the value of the Q-factor decreases. As discussed above, however, conventional wisdom has held that use of resonators with low Q-factor values would result in tunable lasers with unacceptable SMSRs.

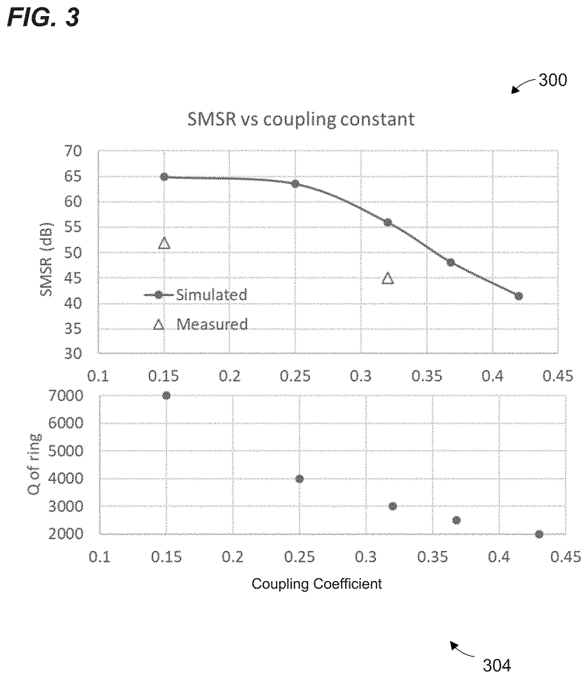

FIG. 3 is a plot 300 of SMSR of the tunable laser device 100 versus a coupling coefficient (κ², which will be discussed in more detail below), and a plot 304 of the Q-factor of the ring resonators 128, 132 versus the coupling coefficient, according to an embodiment. As can be seen in the plot 304, the Q-factor of the ring resonators 128, 132 is related to the coupling coefficient. The coupling coefficient indicates a degree of optical coupling associated with the ring resonators 128, 132. Taking the plot 300 and the plot 304 together, it can be seen that a Q factor above approximately 2500 results in a measured SMSR above 35 decibels (dB), and the SMSR increases as the Q-factor increases.

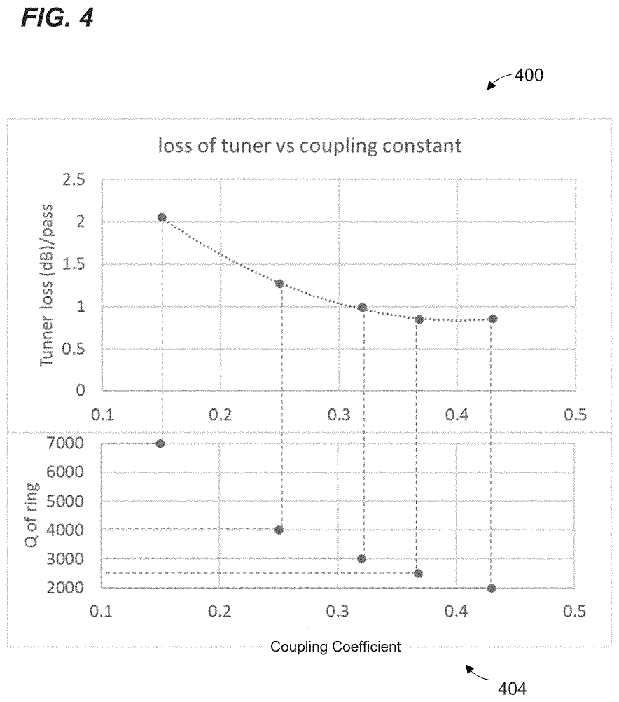

FIG. 4 is a plot 400 of loss in the wavelength tuner 108 versus a coupling coefficient (which will be discussed in more detail below), and a plot 404 of the Q-factor of the ring resonators 128, 132 versus the coupling coefficient, according to an embodiment. Taking the plot 400 and the plot 404 together, it can be seen that tuner loss decreases as the Q-factor decreases until the Q-factor reaches approximately 2500. For Q-factor values below 2500 the tuner loss remains approximately constant, in an embodiment.

Referring again to FIG. 1, respective Q-factors of the ring resonator 128 and the ring resonator 132 are chosen to provide a desired minimum output power and a desired maximum SMSR. In one embodiment, the ring resonator 128 and the ring resonator 132 are configured with respective Q-factors of approximately 3000 (i.e., 3000±150), which provides an output power of the tunable laser 100 of at least 18 dBm and an SMSR of at least 35 dB. In other embodiments, the ring resonator 128 and the ring resonator 132 are configured with respective Q-factors of other suitable values. In some embodiments, the ring resonator 128 and the ring resonator 132 are configured with respective Q-factors between 2000 and 4000. In some embodiments, the ring resonator 128 and the ring resonator 132 are configured with respective Q-factors between 2000 and 3500. In some embodiments, the ring resonator 128 and the ring resonator 132 are configured with respective Q-factors between 2500 and 3500. In some embodiments, the ring resonator 128 and the ring resonator 132 are configured with respective Q-factors between 2500 and 3250.

Light traveling through the wavelength tuner 108 has a relatively low intensity, thus optical loss in the wavelength tuner 108 does not adversely affect light intensity. The reflector 144, having high-reflectivity, effectively extends the laser cavity of the RSOA 104 from the back-end 116 to the reflector 144. At the same time, the front-end 112 of the RSOA 104 is characterized by a low reflectivity (e.g., between 1% and 10%) representing a desired output port reflectivity for the tunable laser device 100, according to some embodiments. Generally, lowering the reflectivity of the front-end 112 tends to increase the output power of the tunable laser 100, according to some embodiments. Additionally, light with a lower intensity (before amplification by the RSOA 104) will suffer a loss by passing though the wavelength tuner 108 and returning to the RSOA 104. As discussed above, however, the loss of the wavelength tuner 108 is relatively low. After the laser light intensity is amplified by the RSOA 104, the light is output with a minimal loss through the low-reflectivity front-end 112.

Thus, the example tunable laser 100 has a low tuner loss and can output high-power light in higher efficiency with a wide-band tunability, while keeping power consumption low. Unlike some conventional tunable lasers that include multiple gain chips, the tunable laser 100 achieves high output power with only a single gain chip, which helps to reduce power consumption as compared to multi-gain chip tunable lasers.

The ring resonator 128 is optically coupled to the waveguides 136, 140 via optical coupling regions 160, and the ring resonator 132 is optically coupled to the waveguides 140, 148 via optical coupling regions 164. The optical coupling regions 160 are configured to provide the ring resonator 128 with a Q-factor between 2000 and 4000, and the optical coupling regions 164 are configured to provide the ring resonator 132 with a Q-factor between 2000 and 4000, according to an embodiment.

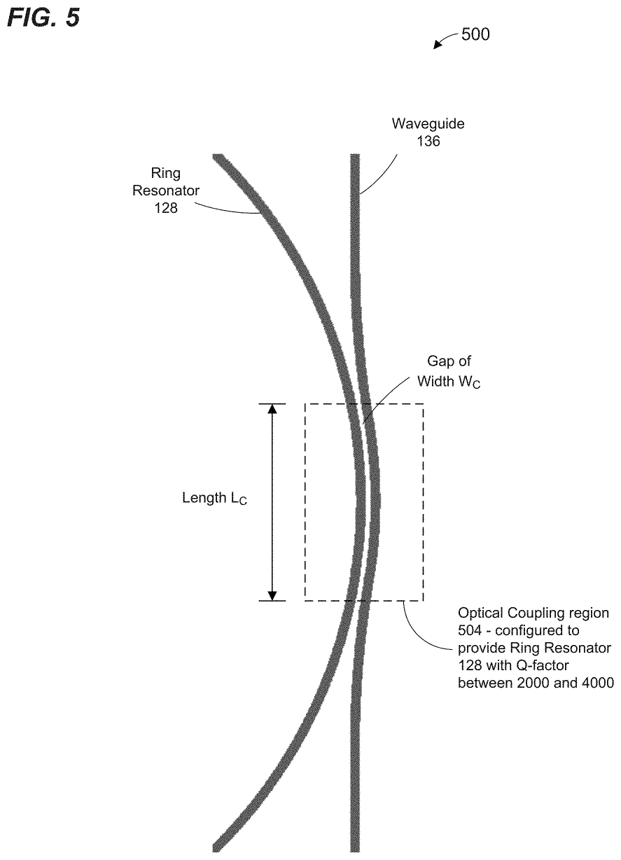

FIG. 5 is a diagram 500 of a section of the ring resonator 128 and a section of the waveguide 136 of FIG. 1, magnified to illustrate an optical coupling of the ring resonator 128 and the waveguide 136, according to an embodiment.

A waveguide of the ring resonator 128 and the waveguide 136 are arranged to be in proximity to one another in an optical coupling region 504. In an embodiment, the optical coupling region 504 corresponds to the optical coupling 160-1 illustrated in FIG. 1. Within the optical coupling region 504, the waveguide of the ring resonator 128 and the waveguide 136 are separated by a gap of width W_{C} for a length of L_{C}. The gap width W_{C} and the length L_{C} of the optical coupling region 504 are selected to achieve a desired degree of optical coupling between the ring resonator 128 and the waveguide 136, where the degree of optical coupling corresponds to a coupling coefficient (κ²) discussed above. Referring again to FIGS. 3 and 4, the plot 304 and the plot 404 illustrate that the coupling coefficient (κ²) is related to the Q-factor of the ring resonators 128, 132. Thus, the gap width W_{C} and the length L_{C} of the optical coupling region 504 are selected to achieve a desired degree of optical coupling between the ring resonator 128 and the waveguide 136, which corresponds to a desired Q-factor for the ring resonator 128.

In an embodiment in which ridge-type waveguides with a waveguide width of 0.3 μm are utilized, selection of the gap width W_{C} as approximately 0.3 μm (i.e., 0.3 μm±0.015 μm) and selection of the length L_{C} of the optical coupling region 504 to be between approximately 3 μm and 7 μm (i.e., between 2.985 μm and 7.015 μm) will result in a ring resonator having a Q-factor of between approximately 2000 and 4000.

Referring now to FIGS. 1 and 5, the optical coupling regions 160-2, 164-1, and 164-2 are structured similarly to the coupling region 504, in some embodiments.

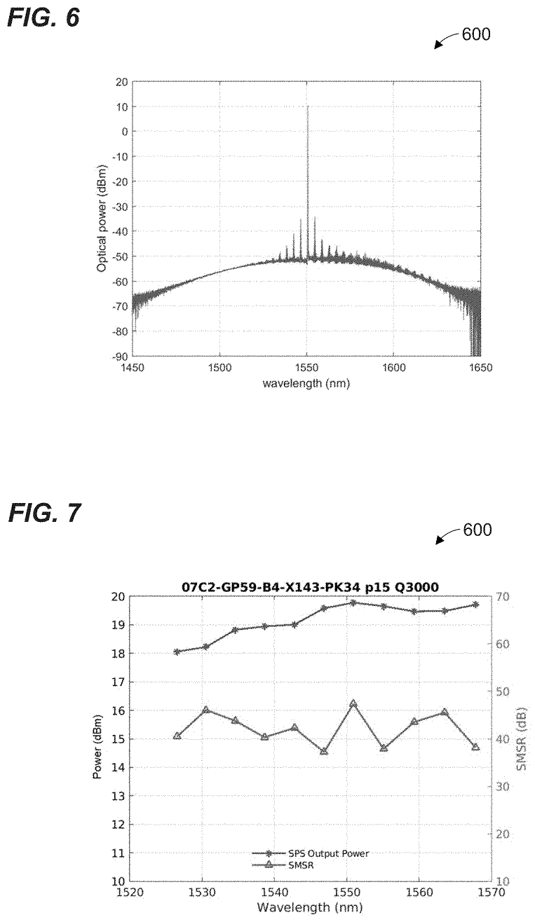

FIG. 6 is a plot 600 of optical output power of the tunable laser 100 versus wavelength, with the ring resonator 128 and the ring resonator 132 configured to have Q-factors of approximately 3000, according to an embodiment. FIG. 7 is a plot 700 of optical output power and SMSR of the tunable laser 100 versus wavelength at 600 milliamps (mA) and with the ring resonator 128 and the ring resonator 132 configured to have Q-factors of approximately 3000, according to an embodiment. As can be seen in plot 700, the optical output power remains above 18 dBm and the SMSR remains above 35 dB.

In various embodiments, an optical waveguide described herein includes a region of high refractive index surrounded by a lower refractive index material. For example, the waveguide may include a raised channel or ridge of comparatively higher refractive index material (such as silicon, doped silicon, or other comparatively higher refractive index material) surrounded on one or more sides by a material of comparatively lower refractive index material (e.g., such as air, silicon dioxide, or other comparatively lower refractive index material).

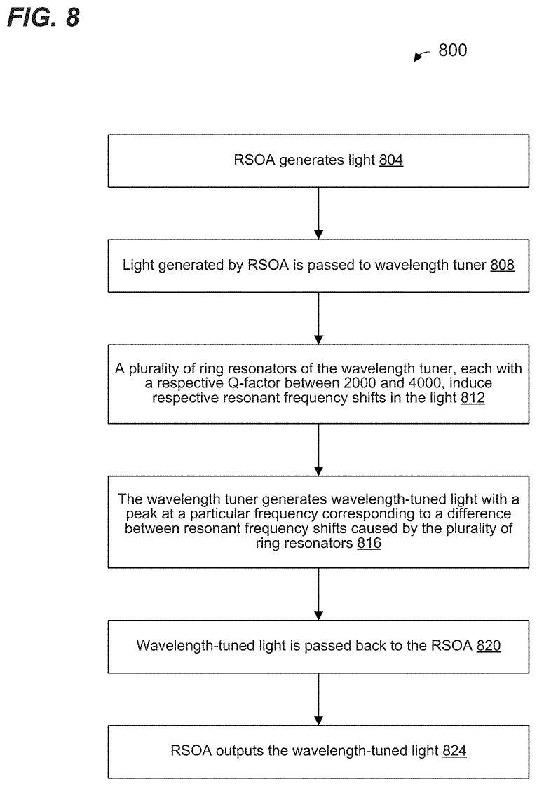

FIG. 8 is a flow diagram of an example method 800 of operation of a tunable laser to generate and output wavelength-tuned light using only a single gain chip, according to an embodiment. The method 800 is performed by any of the embodiments of tunable lasers described herein, including the example tunable laser 100 of FIG. 1, in various embodiments, and FIG. 8 is described with reference to FIG. 1 for ease of explanation. In other embodiments, the method 800 is performed by another suitable tunable laser different than the tunable laser 100 of FIG. 1 and/or other embodiments described herein.

At block 804, an RSOA generates light. For example, the RSOA 104 generates light, in an embodiment.

At block 808, light generated by the RSOA is passed to a wavelength tuner via a back-end of the RSOA. For example, light generated by the RSOA 104 is passed to the wavelength tuner 108 via the back-end 116 of the RSOA 104, in an embodiment.

At block 812, a plurality of ring resonators of the wavelength tuner, each with a respective Q-factor between 2000 and 4000, induce respective resonant frequency shifts in the light. For example, the ring resonator 128 and the ring resonator 132 induce respective resonant frequency shifts in the light, in an embodiment.

At block 816, the wavelength tuner generates wavelength-tuned light with a peak at a particular frequency corresponding to a difference between resonant frequency shifts caused by the plurality of ring resonators. For example, the wavelength tuner 108 generates wavelength-tuned light with a peak at a particular frequency corresponding to a difference between resonant frequency shifts caused by the ring resonator 128 and the ring resonator 132, in an embodiment.

At block 820, the wavelength-tuned light is passed back to the RSOA via the back-end of the RSOA. For example, wavelength-tuned light is passed back to the RSOA 104 via the back-end 116 of the RSOA 104, in an embodiment.

At block 824, the RSOA outputs the wavelength-tuned light via a front-end of the RSOA. For example, the RSOA 104 outputs wavelength-tuned light via the front-end 112 of the RSOA 104, in an embodiment.

In some embodiments, the method 800 optionally further comprises passing light between the RSOA and the plurality of ring resonators, and between ring resonators among the plurality of ring resonators, via a plurality of waveguides; and optically coupling the plurality of resonators to the plurality of waveguides via optical couplings that are configured to provide the plurality of ring resonators with respective Q-factors above 2000 and below 4000.

In some embodiments, passing light between the RSOA and the plurality of ring resonators, and between ring resonators among the plurality of ring resonators, comprises: passing light from the back-end of the RSOA to a first ring resonator, among the plurality of ring resonators, via a first waveguide among the plurality of waveguides; and passing light from the first ring resonator to a second ring resonator, among the plurality of ring resonators, via a second waveguide among the plurality of waveguides. For example, light is passed between the RSOA and the ring resonator 128 via the waveguide 136; and light is passed between the ring resonator 128 and the ring resonator 132 via the waveguide 140, in an embodiment.

In an embodiment, passing light between ring resonators among the plurality of ring resonators comprises: optically coupling the first waveguide to the first ring resonator via a first optical coupling that is configured to provide the first ring resonator with a first Q-factor above 2000 and below 4000; optically coupling the second waveguide to the first ring resonator via a second optical coupling that is configured to provide the first ring resonator with a first Q-factor above 2000 and below 4000; and optically coupling the second waveguide to the second ring resonator via a third optical coupling that is configured to provide the second ring resonator with a first Q-factor above 2000 and below 4000. For example, the waveguide 136 is optically coupled to the ring resonator 128 via the optical coupling 160-1 that is configured to provide the ring resonator 128 a Q-factor between 2000 and 4000; the waveguide 140 is optically coupled to the ring resonator 128 via the optical coupling 160-2 that is configured to provide the ring resonator 128 a Q-factor between 2000 and 4000; and the waveguide 140 is optically coupled to the ring resonator 132 via the optical coupling 164-1 that is configured to provide the ring resonator 132 a Q-factor between 2000 and 4000, according to an embodiment.

In an embodiment, the method 800 further comprises: passing light from the second ring resonator to a reflector via a third waveguide; and optically coupling the third waveguide to the second ring resonator via a fourth optical coupling that is configured to provide the second ring resonator with a first Q-factor above 2000 and below 4000. For example, the waveguide 148 passes light between the ring resonator 132 and the reflector 144; and the ring resonator 132 is optically coupled to the waveguide 148 via the optical coupling 164-2 that is configured to provide the ring resonator 132 a Q-factor between 2000 and 4000, according to an embodiment.

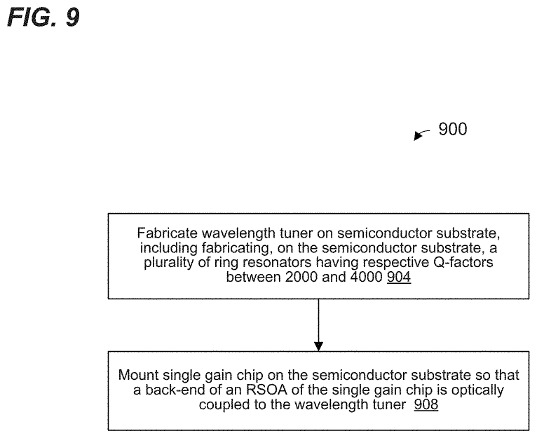

FIG. 9 is a flow diagram of an example method 900 of manufacturing a tunable laser that is configured to generate and output wavelength-tuned light using only a single gain chip, according to an embodiment. The method 900 is performed to manufacture any of the embodiments of tunable lasers described herein, including the example tunable laser 100 of FIG. 1, in various embodiments. In other embodiments, the method 900 is performed to manufacture another suitable tunable laser different than the tunable laser 100 of FIG. 1 and/or other embodiments of tunable lasers described herein.

At block 904, a wavelength tuner is fabricated on a semiconductor substrate, including fabricating on the semiconductor substrate a plurality of ring resonators having respective Q-factors above 2000 and below 4000.

At block 908, a single gain chip is mounted on the semiconductor substrate, the single gain chip comprising an RSOA with a front-end configured to output wavelength-tuned light, wherein the single gain chip is mounted so that a back-end of the RSOA is optically coupled to the wavelength tuner.

In an embodiment, fabricating the wavelength tuner on the semiconductor substrate at block 904 optionally comprises: fabricating a plurality of waveguides on the semiconductor substrate that are optically coupled to the plurality of ring resonators via optical couplings that are configured to provide the ring resonators with respective Q-factors above 2000 and below 4000.

In another embodiment, fabricating the wavelength tuner on the semiconductor substrate at block 904 comprises: fabricating a first waveguide, among the plurality of waveguides, on the semiconductor substrate, including fabricating the first waveguide to be optically coupled to the back-end of the RSOA when the gain chip is mounted to the semiconductor substrate, and so that the first waveguide is optically coupled to a first ring resonator, among the plurality of ring resonators, via a first optical coupling; and fabricating a second waveguide, among the plurality of waveguides, on the semiconductor substrate, so that the second waveguide is optically coupled to the first ring resonator via a second optical coupling, and is optically coupled to a second ring resonator, among the plurality of ring resonators, via a third optical coupling. In an embodiment, the first waveguide and the first resonator are fabricated on the semiconductor substrate so that the first optical coupling comprises a first section of the first waveguide that is disposed proximate to a first section of the first ring resonator at a first gap width W for a first length L; the second waveguide and the first resonator are fabricated on the semiconductor substrate so that the second optical coupling comprises a first section of the second waveguide that is disposed proximate to a second section of the first ring resonator at a second gap width W for a second length L; and the first waveguide, the second waveguide, and the first resonator are fabricated on the semiconductor substrate so that the first gap width W, the first length L, the second gap width W, and the second length L are configured to provide the first ring resonator with a first Q-factor above 2000 and below 4000.

In another embodiment, fabricating the wavelength tuner on the semiconductor substrate at block 904 further comprises: fabricating the second waveguide and the third optical coupling so that a second section of the second waveguide is disposed proximate to a first section of the second ring resonator at a third gap width W for a third length L; fabricating a third waveguide on the semiconductor substrate so that the third waveguide is optically coupled to the second ring resonator via a fourth optical coupling; the third waveguide and the second ring resonator are fabricated so that the fourth optical coupling comprises a first section of the third waveguide that is disposed proximate to a second section of the second ring resonator at a fourth gap width W for a fourth length L; and the third gap width W, the third length L, the fourth gap width W, and the fourth length L are configured to provide the second ring resonator with a first Q-factor above 2000 and below 4000.

In another embodiment, fabricating the wavelength tuner on the semiconductor substrate at block 904 comprises: fabricating, on the semiconductor substrate, a first ring resonator that is configured to cause a first phase shift in light traveling through the first ring resonator; and fabricating, on the semiconductor substrate, a second ring resonator that is configured to cause a second phase shift in light traveling through the second ring resonator, the second phase shift being different than the first phase shift; fabricating the wavelength tuner so that the wavelength tuner is configured to generate a light interference spectrum with a peak at a wavelength that depends on a difference between the first phase shift and the second phase shift.

In another embodiment, fabricating the wavelength tuner on the semiconductor substrate at block 904 comprises: fabricating, on the semiconductor substrate, a reflector optically coupled to the plurality of ring resonators.

In another embodiment, mounting the single gain chip on the semiconductor substrate at block 908 comprises flip-mounting the single gain chip to the semiconductor substrate.

Embodiment 1: A tunable laser for generating and outputting wavelength-tuned light using only a single gain chip, comprising: a reflective semiconductor optical amplifier (RSOA) having a front-end configured as an output port for outputting the wavelength-tuned light with an amplified light intensity relative to light received at a back-end of the RSOA; and a wavelength tuner optically coupled to the back-end of the RSOA, the wavelength tuner comprising a plurality of ring resonators having respective Q-factors above 2000 and below 4000.

Embodiment 2: The tunable laser of embodiment 1, wherein the wavelength tuner further comprises: a plurality of waveguides optically coupled to the plurality of ring resonators via optical couplings that are configured to provide the ring resonators with respective Q-factors above 2000 and below 4000.

Embodiment 3: The tunable laser of embodiment 2, wherein: a first waveguide, among the plurality of waveguides, is optically coupled to the back-end of the RSOA and is optically coupled to a first ring resonator, among the plurality of ring resonators, via a first optical coupling; and a second waveguide, among the plurality of waveguides, is optically coupled to the first ring resonator via a second optical coupling, and is optically coupled to a second ring resonator, among the plurality of ring resonators, via a third optical coupling; the first optical coupling comprises a first section of the first waveguide that is disposed proximate to a first section of the first ring resonator at a first gap width W for a first length L; the second optical coupling comprises a first section of the second waveguide that is disposed proximate to a second section of the first ring resonator at a second gap width W for a second length L; and the first gap width W, the first length L, the second gap width W, and the second length L are configured to provide the first ring resonator with a first Q-factor above 2000 and below 4000.

Embodiment 4: The tunable laser of embodiment 3, wherein: the wavelength tuner further comprising a third waveguide optically coupled to the second ring resonator via a fourth optical coupling; and the third optical coupling comprises a second section of the second waveguide that is disposed proximate to a first section of the second ring resonator at a third gap width W for a third length L; the fourth optical coupling comprises a first section of the third waveguide that is disposed proximate to a second section of the second ring resonator at a fourth gap width W for a fourth length L; and the third gap width W, the third length L, the fourth gap width W, and the fourth length L are configured to provide the second ring resonator with a first Q-factor above 2000 and below 4000.

Embodiment 5: The tunable laser of any of embodiments 1-4, wherein the wavelength tuner comprises: a first ring resonator that is configured to cause a first phase shift in light traveling through the first ring resonator; and a second ring resonator that is configured to cause a second phase shift in light traveling through the second ring resonator, the second phase shift being different than the first phase shift; wherein the wavelength tuner is configured to generate a light interference spectrum with a peak at a wavelength that depends on a difference between the first phase shift and the second phase shift.

Embodiment 6: The tunable laser of any of embodiments 1-5, wherein: the wavelength tuner further comprising a reflector optically coupled to the plurality of ring resonators, the reflector configured to receive light from the plurality of ring resonators and reflect a substantial portion of the received light back to the plurality or ring resonators.

Embodiment 7: The tunable laser of any of embodiments 1-6, wherein: the wavelength tuner is formed on a semiconductor substrate; and the RSOA is housed on a chip that is mounted to the semiconductor substrate.

Embodiment 8: The tunable laser of any of embodiments 1-7, wherein: the plurality of ring resonators have respective Q-factors above 2000 and below 3500.

Embodiment 9: The tunable laser of any of embodiments 1-8, wherein: the plurality of ring resonators have respective Q-factors above 2500 and below 3500.

Embodiment 10: The tunable laser of any of embodiments 1-9, wherein: the plurality of ring resonators have respective Q-factors above 2500 and below 3250.

Embodiment 11: A method of operation of a single gain chip tunable laser, the method comprising: generating, by an RSOA, light; passing the light generated by the RSOA to a wavelength tuner via a back-end of the RSOA; and inducing respective frequency shifts in the light by a plurality of ring resonators of the wavelength tuner, each ring resonator having a respective quality factor (Q-factor) between 2000 and 4000; generating, with the wavelength tuner, wavelength-tuned light having a peak at a particular frequency corresponding to a difference between resonant frequency shifts caused by the plurality of ring resonators; passing the wavelength-tuned light back to the RSOA via the back-end of the RSOA; and outputting the wavelength-tuned light from the RSOA via a front-end of the RSOA.

Embodiment 12: The method of operation of the single gain chip tunable laser of embodiment 11, further comprising: passing light between the RSOA and the plurality of ring resonators, and between ring resonators among the plurality of ring resonators, via a plurality of waveguides; and optically coupling the plurality of resonators to the plurality of waveguides via optical couplings that are configured to provide the plurality of ring resonators with respective Q-factors above 2000 and below 4000.

Embodiment 13: The method of operation of the single gain chip tunable laser of embodiment 12, wherein passing light between the RSOA and the plurality of ring resonators, and between ring resonators among the plurality of ring resonators, comprises: passing light from the back-end of the RSOA to a first ring resonator, among the plurality of ring resonators, via a first waveguide among the plurality of waveguides; and passing light from the first ring resonator to a second ring resonator, among the plurality of ring resonators, via a second waveguide among the plurality of waveguides.

Embodiment 14: The method of operation of the single gain chip tunable laser of embodiment 13, wherein passing light between ring resonators among the plurality of ring resonators comprises: optically coupling the first waveguide to the first ring resonator via a first optical coupling that is configured to provide the first ring resonator with a first Q-factor above 2000 and below 4000; optically coupling the second waveguide to the first ring resonator via a second optical coupling that is configured to provide the first ring resonator with a first Q-factor above 2000 and below 4000; and optically coupling the second waveguide to the second ring resonator via a third optical coupling that is configured to provide the second ring resonator with a first Q-factor above 2000 and below 4000.

Embodiment 15: The method of operation of the single gain chip tunable laser of embodiment 14, further comprising: passing light from the second ring resonator to a reflector via a third waveguide; and optically coupling the third waveguide to the second ring resonator via a fourth optical coupling that is configured to provide the second ring resonator with a first Q-factor above 2000 and below 4000.

Embodiment 16: The method of operation of the single gain chip tunable laser of any of embodiments 11-15, wherein each ring resonator has a respective Q-factor above 2000 and below 3500.

Embodiment 17: The method of operation of the single gain chip tunable laser of any of embodiments 11-16, wherein each ring resonator has a respective Q-factor above 2500 and below 3500.

Embodiment 18: The method of operation of the single gain chip tunable laser of any of embodiments 11-17, wherein each ring resonator has a respective Q-factor above 2500 and below 3250.

Embodiment 19: A method of manufacturing a tunable laser that is configured to generate and output wavelength-tuned light using only a single gain chip, the method comprising: fabricating a wavelength tuner on a semiconductor substrate, including fabricating on the semiconductor substrate a plurality of ring resonators having respective Q-factors above 2000 and below 4000; and mounting the single gain chip on the semiconductor substrate, the single gain chip comprising an RSOA with a front-end configured to output wavelength-tuned light, wherein the single gain chip is mounted so that a back-end of the RSOA is optically coupled to the wavelength tuner.

Embodiment 20: The method of manufacturing a tunable laser of embodiment 19, wherein fabricating the wavelength tuner on the semiconductor substrate comprises: fabricating a plurality of waveguides on the semiconductor substrate that are optically coupled to the plurality of ring resonators via optical couplings that are configured to provide the ring resonators with respective Q-factors above 2000 and below 4000.

Embodiment 21: The method of manufacturing a tunable laser of embodiment 20, wherein fabricating the wavelength tuner on the semiconductor substrate further comprises: fabricating a first waveguide, among the plurality of waveguides, on the semiconductor substrate, including fabricating the first waveguide to be optically coupled to the back-end of the RSOA when the gain chip is mounted to the semiconductor substrate, and so that the first waveguide is optically coupled to a first ring resonator, among the plurality of ring resonators, via a first optical coupling; and fabricating a second waveguide, among the plurality of waveguides, on the semiconductor substrate, so that the second waveguide is optically coupled to the first ring resonator via a second optical coupling, and is optically coupled to a second ring resonator, among the plurality of ring resonators, via a third optical coupling.

Embodiment 22: The method of manufacturing a tunable laser of embodiment 21, wherein fabricating the wavelength tuner on the semiconductor substrate further comprises: fabricating the first waveguide and the first resonator on the semiconductor substrate so that the first optical coupling comprises a first section of the first waveguide that is disposed proximate to a first section of the first ring resonator at a first gap width W for a first length L; fabricating the second waveguide and the first resonator on the semiconductor substrate so that the second optical coupling comprises a first section of the second waveguide that is disposed proximate to a second section of the first ring resonator at a second gap width W for a second length L; and fabricating the first waveguide, the second waveguide, and the first resonator on the semiconductor substrate so that the first gap width W, the first length L, the second gap width W, and the second length L are configured to provide the first ring resonator with a first Q-factor above 2000 and below 4000.

Embodiment 23: The method of manufacturing a tunable laser of embodiment 22, wherein fabricating the wavelength tuner on the semiconductor substrate further comprises: fabricating the second waveguide and the third optical coupling so that a second section of the second waveguide is disposed proximate to a first section of the second ring resonator at a third gap width W for a third length L; fabricating a third waveguide on the semiconductor substrate so that the third waveguide is optically coupled to the second ring resonator via a fourth optical coupling; fabricating the third waveguide and the second ring resonator so that the fourth optical coupling comprises a first section of the third waveguide that is disposed proximate to a second section of the second ring resonator at a fourth gap width W for a fourth length L; and wherein the third gap width W, the third length L, the fourth gap width W, and the fourth length L are configured to provide the second ring resonator with a second Q-factor above 2000 and below 4000.

Embodiment 24: The method of manufacturing a tunable laser of any of embodiments 19-23, wherein fabricating the wavelength tuner on the semiconductor substrate comprises: fabricating, on the semiconductor substrate, a first ring resonator that is configured to cause a first phase shift in light traveling through the first ring resonator; fabricating, on the semiconductor substrate, a second ring resonator that is configured to cause a second phase shift in light traveling through the second ring resonator, the second phase shift being different than the first phase shift; and fabricating the wavelength tuner so that the wavelength tuner is configured to generate a light interference spectrum with a peak at a wavelength that depends on a difference between the first phase shift and the second phase shift.

Embodiment 25: The method of manufacturing a tunable laser of any of embodiments 19-24, wherein fabricating the wavelength tuner on the semiconductor substrate comprises: fabricating, on the semiconductor substrate, a reflector optically coupled to the plurality of ring resonators, the reflector configured to receive light from the plurality of ring resonators and reflect a substantial portion of the received light back to the plurality of ring resonators.

Embodiment 26: The method of manufacturing a tunable laser of any of embodiments 19-25, wherein mounting the single gain chip on the semiconductor substrate comprises: flip-mounting the single gain chip to the semiconductor substrate.

Embodiment 27: The method of manufacturing a tunable laser of any of embodiments 19-26, wherein: the plurality of ring resonators have respective Q-factors above 2000 and below 3500.

Embodiment 28: The method of manufacturing a tunable laser of any of embodiments 19-27, wherein: the plurality of ring resonators have respective Q-factors above 2500 and below 3500.

Embodiment 29: The method of manufacturing a tunable laser of any of embodiments 19-28, wherein: the plurality of ring resonators have respective Q-factors above 2500 and below 3250.

While the present disclosure has been described with reference to specific examples, which are intended to be illustrative only and not to be limiting of the invention, changes, additions and/or deletions may be made to the disclosed embodiments without departing from the scope of the invention.

What is claimed is:

1. A tunable laser for generating and outputting wavelength-tuned light using only a single gain chip, comprising:
a reflective semiconductor optical amplifier (RSOA) having a front-end configured as an output port for outputting the wavelength-tuned light with an amplified light intensity relative to light received at a back-end of the RSOA; and
a wavelength tuner optically coupled to the back-end of the RSOA, the wavelength tuner comprising a plurality of ring resonators having respective Q-factors above 2000 and below 4000.

2. The tunable laser of claim 1, wherein the wavelength tuner further comprises:
a plurality of waveguides optically coupled to the plurality of ring resonators via optical couplings that are configured to provide the ring resonators with respective Q-factors above 2000 and below 4000.

3. The tunable laser of claim 2, wherein:
a first waveguide, among the plurality of waveguides, is optically coupled to the back-end of the RSOA and is optically coupled to a first ring resonator, among the plurality of ring resonators, via a first optical coupling;
a second waveguide, among the plurality of waveguides, is optically coupled to the first ring resonator via a second optical coupling, and is optically coupled to a second ring resonator, among the plurality of ring resonators, via a third optical coupling;
the first optical coupling comprises a first section of the first waveguide that is disposed proximate to a first section of the first ring resonator at a first gap width W for a first length L;
the second optical coupling comprises a first section of the second waveguide that is disposed proximate to a second section of the first ring resonator at a second gap width W for a second length L; and
the first gap width W, the first length L, the second gap width W, and the second length L are configured to provide the first ring resonator with a first Q-factor above 2000 and below 4000.

4. The tunable laser of claim 3, wherein:
the wavelength tuner further comprising a third waveguide optically coupled to the second ring resonator via a fourth optical coupling;
the third optical coupling comprises a second section of the second waveguide that is disposed proximate to a first section of the second ring resonator at a third gap width W for a third length L;
the fourth optical coupling comprises a first section of the third waveguide that is disposed proximate to a second section of the second ring resonator at a fourth gap width W for a fourth length L; and
the third gap width W, the third length L, the fourth gap width W, and the fourth length L are configured to provide the second ring resonator with a first Q-factor above 2000 and below 4000.

5. The tunable laser of claim 1, wherein the wavelength tuner comprises:
a first ring resonator that is configured to cause a first phase shift in light traveling through the first ring resonator; and
a second ring resonator that is configured to cause a second phase shift in light traveling through the second ring resonator, the second phase shift being different than the first phase shift;
wherein the wavelength tuner is configured to generate a light interference spectrum with a peak at a wavelength that depends on a difference between the first phase shift and the second phase shift.

6. The tunable laser of claim 1, wherein:
the wavelength tuner further comprising a reflector optically coupled to the plurality of ring resonators, the reflector configured to receive light from the plurality of ring resonators and reflect a substantial portion of the received light back to the plurality or ring resonators.

7. The tunable laser of claim 1, wherein:
the wavelength tuner is formed on a semiconductor substrate; and
the RSOA is housed on a chip that is mounted to the semiconductor substrate.

8. A method of operation of a single gain chip tunable laser, the method comprising:
generating, by a reflective semiconductor optical amplifier (RSOA), light;
passing the light generated by the RSOA to a wavelength tuner via a back-end of the RSOA;
inducing respective frequency shifts in the light by a plurality of ring resonators of the wavelength tuner, each ring resonator having a respective quality factor (Q-factor) between 2000 and 4000;
generating, with the wavelength tuner, wavelength-tuned light having a peak at a particular frequency corresponding to a difference between resonant frequency shifts caused by the plurality of ring resonators;
passing the wavelength-tuned light back to the RSOA via the back-end of the RSOA; and
outputting the wavelength-tuned light from the RSOA via a front-end of the RSOA.

9. The method of operation of the single gain chip tunable laser of claim 8, further comprising:
passing light between the RSOA and the plurality of ring resonators, and between ring resonators among the plurality of ring resonators, via a plurality of waveguides; and
optically coupling the plurality of resonators to the plurality of waveguides via optical couplings that are configured to provide the plurality of ring resonators with respective Q-factors above 2000 and below 4000.

10. The method of operation of the single gain chip tunable laser of claim 9, wherein passing light between the RSOA and the plurality of ring resonators, and between ring resonators among the plurality of ring resonators, comprises:
passing light from the back-end of the RSOA to a first ring resonator, among the plurality of ring resonators, via a first waveguide among the plurality of waveguides; and
passing light from the first ring resonator to a second ring resonator, among the plurality of ring resonators, via a second waveguide among the plurality of waveguides.

11. The method of operation of the single gain chip tunable laser of claim 10, wherein passing light between ring resonators among the plurality of ring resonators comprises:
optically coupling the first waveguide to the first ring resonator via a first optical coupling that is configured to provide the first ring resonator with a first Q-factor above 2000 and below 4000;
optically coupling the second waveguide to the first ring resonator via a second optical coupling that is configured to provide the first ring resonator with a first Q-factor above 2000 and below 4000; and
optically coupling the second waveguide to the second ring resonator via a third optical coupling that is configured to provide the second ring resonator with a first Q-factor above 2000 and below 4000.

12. The method of operation of the single gain chip tunable laser of claim 10, further comprising:
passing light from the second ring resonator to a reflector via a third waveguide; and
optically coupling the third waveguide to the second ring resonator via a fourth optical coupling that is configured to provide the second ring resonator with a first Q-factor above 2000 and below 4000.

13. A method of manufacturing a tunable laser that is configured to generate and output wavelength-tuned light using only a single gain chip, the method comprising:
fabricating a wavelength tuner on a semiconductor substrate, including fabricating on the semiconductor substrate a plurality of ring resonators having respective Q-factors above 2000 and below 4000; and
mounting the single gain chip on the semiconductor substrate, the single gain chip comprising a reflective semiconductor optical amplifier (RSOA) with a front-end configured to output wavelength-tuned light, wherein the single gain chip is mounted so that a back-end of the RSOA is optically coupled to the wavelength tuner.

14. The method of manufacturing a tunable laser of claim 13, wherein fabricating the wavelength tuner on the semiconductor substrate comprises:
fabricating a plurality of waveguides on the semiconductor substrate that are optically coupled to the plurality of ring resonators via optical couplings that are configured to provide the ring resonators with respective Q-factors above 2000 and below 4000.

15. The method of manufacturing a tunable laser of claim 14, wherein fabricating the wavelength tuner on the semiconductor substrate further comprises:
fabricating a first waveguide, among the plurality of waveguides, on the semiconductor substrate, including fabricating the first waveguide to be optically coupled to the back-end of the RSOA when the gain chip is mounted to the semiconductor substrate, and so that the first waveguide is optically coupled to a first ring resonator, among the plurality of ring resonators, via a first optical coupling; and
fabricating a second waveguide, among the plurality of waveguides, on the semiconductor substrate, so that the second waveguide is optically coupled to the first ring resonator via a second optical coupling, and is optically coupled to a second ring resonator, among the plurality of ring resonators, via a third optical coupling.

16. The method of manufacturing a tunable laser of claim 15, wherein fabricating the wavelength tuner on the semiconductor substrate further comprises:
fabricating the first waveguide and the first resonator on the semiconductor substrate so that the first optical coupling comprises a first section of the first waveguide that is disposed proximate to a first section of the first ring resonator at a first gap width W for a first length L;
fabricating the second waveguide and the first resonator on the semiconductor substrate so that the second optical coupling comprises a first section of the second waveguide that is disposed proximate to a second section of the first ring resonator at a second gap width W for a second length L; and
fabricating the first waveguide, the second waveguide, and the first resonator on the semiconductor substrate so that the first gap width W, the first length L, the second gap width W, and the second length L are configured to provide the first ring resonator with a first Q-factor above 2000 and below 4000.

17. The method of manufacturing a tunable laser of claim 16, wherein fabricating the wavelength tuner on the semiconductor substrate further comprises:
fabricating the second waveguide and the third optical coupling so that a second section of the second waveguide is disposed proximate to a first section of the second ring resonator at a third gap width W for a third length L;
fabricating a third waveguide on the semiconductor substrate so that the third waveguide is optically coupled to the second ring resonator via a fourth optical coupling;
fabricating the third waveguide and the second ring resonator so that the fourth optical coupling comprises a first section of the third waveguide that is disposed proximate to a second section of the second ring resonator at a fourth gap width W for a fourth length L; and
wherein the third gap width W, the third length L, the fourth gap width W, and the fourth length L are configured to provide the second ring resonator with a second Q-factor above 2000 and below 4000.

18. The method of manufacturing a tunable laser of claim 13, wherein fabricating the wavelength tuner on the semiconductor substrate comprises:
fabricating, on the semiconductor substrate, a first ring resonator that is configured to cause a first phase shift in light traveling through the first ring resonator;
fabricating, on the semiconductor substrate, a second ring resonator that is configured to cause a second phase shift in light traveling through the second ring resonator, the second phase shift being different than the first phase shift; and
fabricating the wavelength tuner so that the wavelength tuner is configured to generate a light interference spectrum with a peak at a wavelength that depends on a difference between the first phase shift and the second phase shift.

19. The method of manufacturing a tunable laser of claim 13, wherein fabricating the wavelength tuner on the semiconductor substrate comprises:
fabricating, on the semiconductor substrate, a reflector optically coupled to the plurality of ring resonators, the reflector configured to receive light from the plurality of ring resonators and reflect a substantial portion of the received light back to the plurality of ring resonators.

20. The method of manufacturing a tunable laser of claim 13, wherein mounting the single gain chip on the semiconductor substrate comprises:
flip-mounting the single gain chip to the semiconductor substrate.
